(19) United States
(12) Patent Application Publication
(10) Pub. No.: US 2010/0026543 A1
(43) Pub. Date: Feb. 4, 2010

(54) ANALOG TO DIGITAL CONVERTER

(75) Inventors: Chih-Hou TSAI, Taipei (TW); Wei-Ping WANG, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: ALi Corporation, Taipei (TW)

(21) Appl. No.: 12/487,723

(22) Filed: Jun. 19, 2009

(30) Foreign Application Priority Data
Aug. 1, 2008 (CN) 200810131308.4

(51) Int. Cl. H03M 1/12

(52) U.S. Cl. 341/155

(57) ABSTRACT

An analog to digital converter having an input stage amplifier array, an input stage voltage divider array, a comparator array and an encoder. The input stage amplifier array calculates and amplifies the difference between an input signal and a plurality of reference signals to generate a plurality of amplified differences. The input stage voltage divider array averages every two adjacent amplified differences to generate a plurality of average signals. The comparator array compares the average signals with a threshold value and outputs the compared results to the encoder for digital data representing the value of the input signal.

### CROSS REFERENCE TO RELATED APPLICATIONS

This Application claims priority of China Patent Application No. 200810131308.4, filed on Aug. 1, 2008, the entirety of which is incorporated by reference herein.

### BACKGROUND OF THE INVENTION

1. Field of the Invention

The present invention relates to analog to digital converters (ADCs), and in particular relates to flash ADCs.

2. Description of the Related Art

FIG. 1 illustrates a conventional flash ADC. The input stage comprises an amplifier array 102 comprising amplifiers A₁, A₂, A₃, and A₄. The comparator array 104 comprises comparators C₁, C₂, C₃ and C₄. The latch array 106 comprises latches L₁, L₂, L₃, and L₄. In additional to an input signal, Vᵢₙ, the amplifiers A₁, A₂, A₃, and A₄ further receive reference voltage values V₁, V₂, V₃, and V₄, respectively. The progressively increasing, or decreasing reference voltage values V₁, V₂, V₃, and V₄ may be provided by a voltage ladder (not shown in the figure).

The amplifier array 102 calculates and amplifies the differences between the input signal Vᵢₙ and the reference voltage values V₁, V₂, V₃ and V₄, and outputs amplified differences ad₁, ad₂, ad₃ and ad₄. The comparator array 104 compares the amplified differences ad₁, ad₂, ad₃ and ad₄ with a threshold value (such as 0 volt) to output compared results cr₁, cr₂, cr₃ and cr₄. The latch array 106 works as an encoder, transforming the compared results cr₁, cr₂, cr₃ and cr₄ to digital data D₁, D₂, D₃, D₄ to label the value of the analog input signal Vᵢₙ.

The conventional flash ADC comprises a large number of amplifiers (A₁, A₂, A₃ and A₄) and a large number of comparators (C₁, C₂, C₃ and C₄). The conventional flash ADC may malfunction because of defects, such as noise defects or offset defects, of the amplifiers (A₁, A₂, A₃ and A₄) and comparators (C₁, C₂, C₃ and C₄).

### BRIEF SUMMARY OF THE INVENTION

The invention discloses analog to digital converters (ADCs). An exemplary embodiment of the ADC comprises an input stage amplifier array, an input stage voltage divider array, a comparator array and an encoder. The input stage amplifier array calculates and amplifies differences between an input signal and a plurality of reference signals to generate a plurality of amplified differences. The input stage voltage divider array averages every two adjacent amplified differences to generate a plurality of average signals. The comparator array compares the average signals with a threshold value to generate a plurality of compared results. The encoder transforms the compared results to digital data to label the value of the input signal.

In another exemplary embodiment of the invention, the ADC comprises an input stage amplifier array, an input stage voltage divider array, an intermediate stage amplifier array, an intermediate stage voltage divider array, a comparator array and an encoder. The input stage amplifier array calculates and amplifies differences between an input signal and a plurality of reference signals to generate a plurality of amplified differences. The input stage voltage divider array averages every two adjacent amplified differences to generate a plurality of average signals. The intermediate stage amplifier array, amplifies the average signals to generate a plurality of intermediate amplified signals. The intermediate stage voltage divider array averages every two adjacent intermediate amplified signals to generate a plurality of intermediate average signals to be coupled to the comparator array. The comparator array compares the received signals with a threshold value to output a plurality of compared results. The encoder transforms the compared results to digital data to label the value of the input signal.

In another exemplary embodiment of the invention, the ADC comprises an input stage amplifier array, an intermediate stage amplifier array, an intermediate stage voltage divider array, a comparator array and an encoder. The input stage amplifier array calculates and amplifies differences between an input signal and a plurality of reference signals to generate a plurality of amplified differences. The intermediate stage amplifier array amplifies the amplified differences to generate a plurality of intermediate amplified signals. The intermediate stage voltage divider array averages every two adjacent intermediate amplified signals to generate a plurality of intermediate average signals to be coupled to the comparator array. The comparator array compares the received signals with a threshold value to output a plurality of compared results. The encoder transforms the compared results to digital data to label the value of the input signal.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 illustrates a conventional flash ADC;

FIG. 2 illustrates an embodiment of the ADC of the invention;

FIG. 3 illustrates another embodiment of the ADC of the invention;

FIG. 4 illustrates another embodiment of the ADC of the invention; and

FIG. 5 illustrates an exemplary circuit of the amplifiers A₁ and A₂, and the voltage divider vdᵢ₁.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

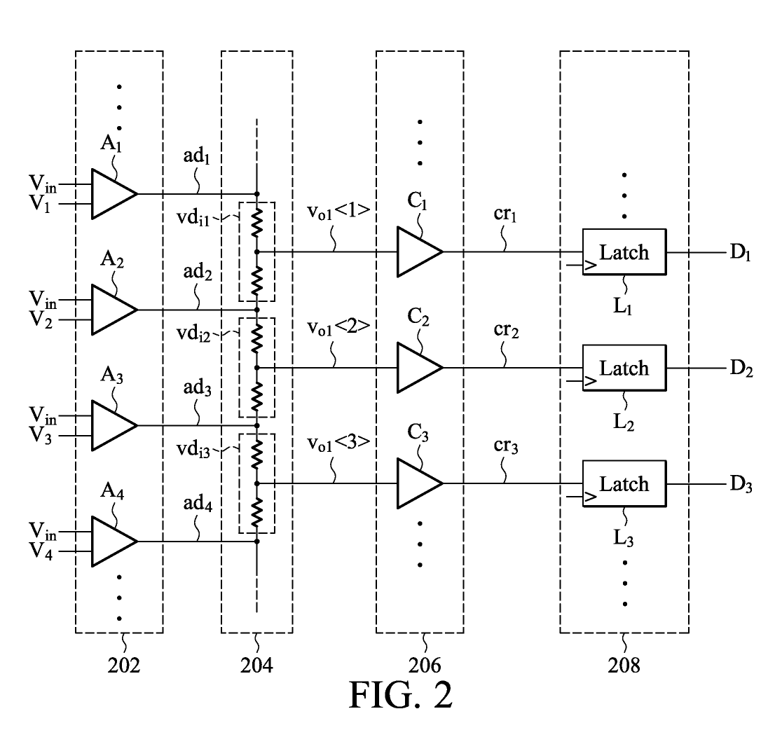

FIG. 2 illustrates an embodiment of the analog to digital converter (ADC) of the invention. The ADC comprises an input stage amplifier array 202, an input stage voltage divider array 204, a comparator array 206 and an encoder 208. As shown in FIG. 2, the encoder 208 may be realized by an array of latches. The input stage amplifier array 202 comprises a plurality of amplifiers A₁, A₂, A₃, and A₄, calculating and amplifying differences between an input signal Vᵢₙ and a plurality of reference signals V₁, V₂, V₃, and V₄ to generate amplified differences ad₁, ad₂, ad₃, and ad₄. The reference signals V₁, V₂, V₃, and V₄ may be progressively increasing or decreasing voltage values outputted from a voltage ladder (not shown in the figure). The input stage voltage divider array 204 comprises voltage dividers vdᵢ₁, vdᵢ₂, and vdᵢ₃. Each voltage divider (vdᵢ₁, vdᵢ₂, and vdᵢ₃) may comprise two equivalent resistors that are coupled in series. The voltage dividers vdᵢ₁, vdᵢ₂ and vdᵢ₃ are inserted between the output terminals of the amplifiers A₁, A₂, A₃, and A₄ to average the adjacent amplified differences to generate average signals vₒ₁<1>, vₒ₁<2>, and vₒ₁<3>. For example, the voltage divider vdᵢ₁ averages the amplified differences ad₁ and ad₂ to generate the average signal vₒ₁<1>; and the voltage divider vdᵢ₂ averages the amplified differences ad₂ and ad₃ to generate the average signal vₒ₁<2> and so on.

The comparator array 206 comprises comparators C₁, C₂, and C₃, comparing the average signals vₒ₁<1>, vₒ₁<2> and vₒ₁<3> with a threshold value (such as 0 volt) to generate compared results cr₁, cr₂ and cr₃. The latch array 208 transforms the compared results cr₁, cr₂ and cr₃ to digital data D₁, D₂ and D₃ to label the input signal Vᵢₙ. The latch array 208 (comprising latches L₁, L₂, and L₃ . . . ) may be replaced by other circuits having an encoding function.

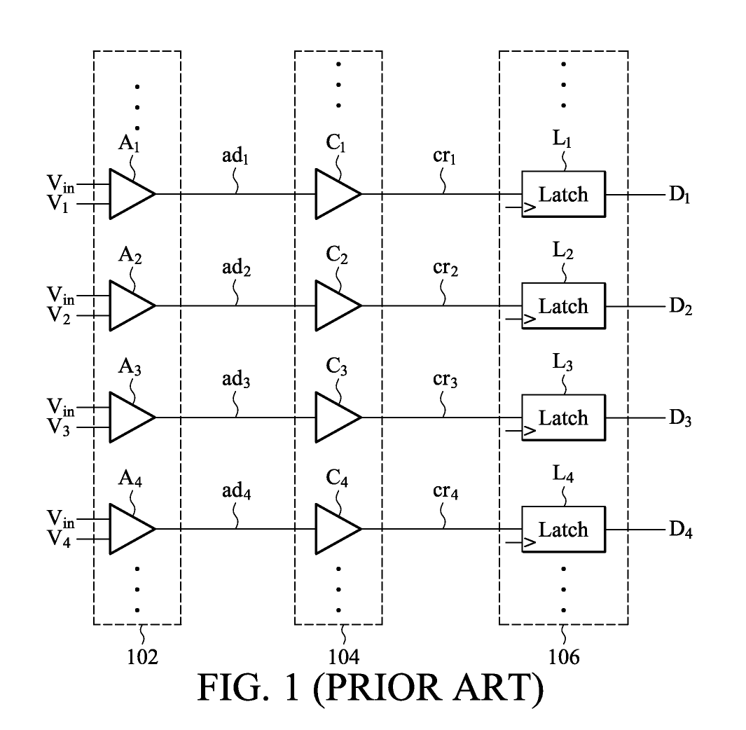

The ADC of FIG. 2 has a much better performance than the conventional ADC of FIG. 1. The following compares the digital data D₂ of FIGS. 1 and 2. In FIG. 1, the digital signal D₂ is usually critically damaged by the noise and offset defects of the amplifier A₂. In FIG. 2, however, the voltage divider vdᵢ₂ counteracts the noise and offset defects of the amplifiers A₂ and A₃, and improves the quality of the digital signal D₂.

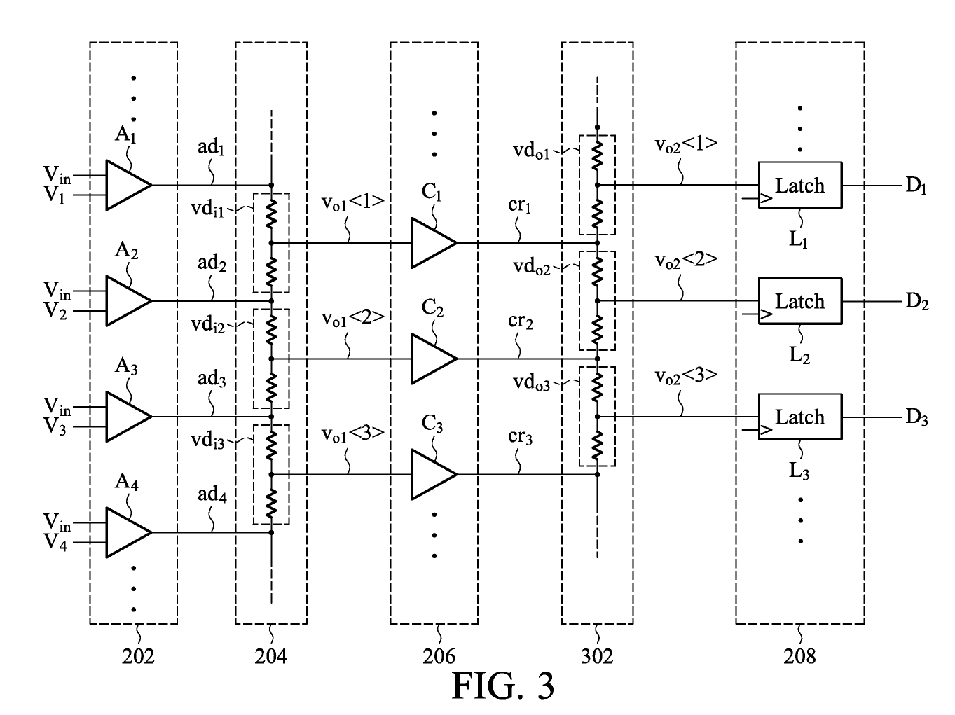

FIG. 3 illustrates another embodiment of the ADC of the invention. Compared with FIG. 2, the ADC of FIG. 3 further comprises an output stage voltage divider array 302 coupled between the comparator array 206 and the latch array 208. The output stage voltage divider array comprises voltage dividers vdₒ₁, vdₒ₂ and vdₒ₃. The voltage dividers vdₒ₁, vdₒ₂ and vdₒ₃ are inserted between the output terminals of the comparators C₁, C₂, and C₃ to average the adjacent compared results and generate average compared results vₒ₂<1>, vₒ₂<2> and vₒ₂<3>. For example, the voltage divider vdₒ₂ averages the adjacent compared results cr₁ and cr₂ to generate the average compared result vₒ₂<2>; and the voltage divider vdₒ₃ averages the adjacent compared results cr2 and cr3 to generate the average compared result vₒ₂<3>, and so on.

The following takes the digital data D₂ as an example. In FIG. 3, the voltage dividers vdᵢ₁ vdᵢ₂, and vdₒ₂ counteracts the noise and offset defects of the amplifiers A₁, A₂ and A₃ and the comparators C₁ and C₂. Thus, the quality of the digital signal D₂ is dramatically improved.

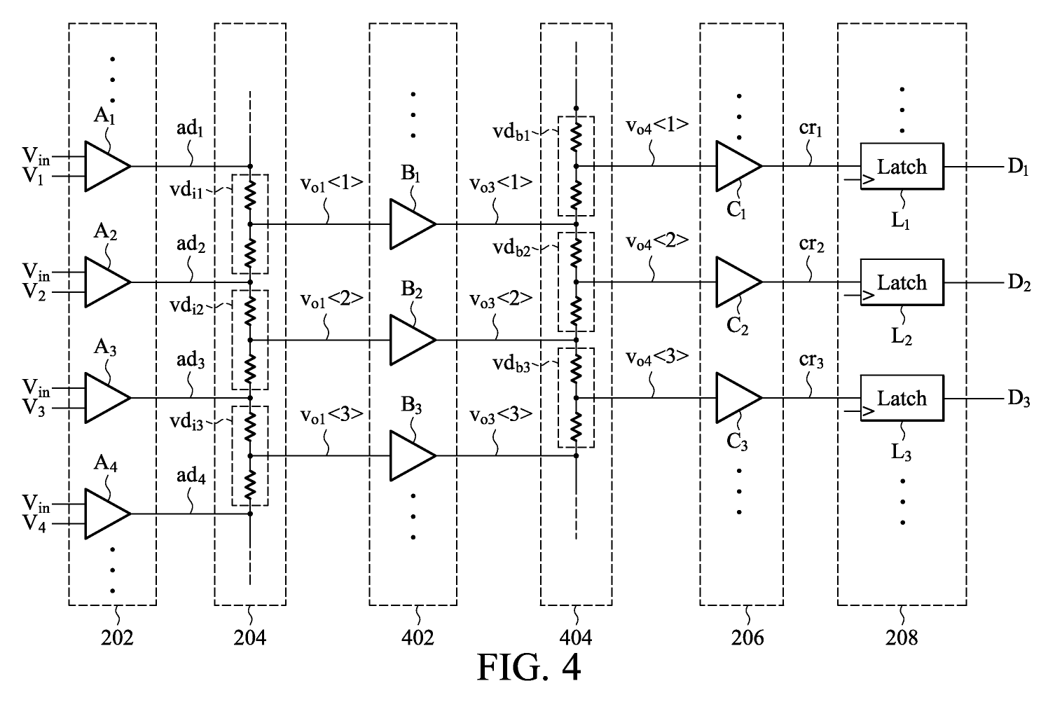

FIG. 4 illustrates another embodiment of the ADC of the invention. Compared with FIG. 2, the ADC of FIG. 4 further comprises an intermediate amplifier array 402 and an intermediate stage voltage divider array 404 coupled between the input stage voltage divider array 204 and the comparator array 206. The intermediate stage amplifier array 402 comprises amplifiers B₁, B₂, and B₃, amplifying the average values vₒ₁<1>, vₒ₁<2>, and vₒ₁<3> to generate intermediate amplified signals vₒ₃<1>, vₒ₃<2>, and vₒ₃<3>. The intermediate stage voltage divider array 404 comprises voltage dividers vd_{b1}, vd_{b2}, and vd_{b3}. Each voltage divider may comprise two equivalent resistors that are coupled in series. The voltage dividers vd_{b1}, vd_{b2}, and vd_{b3} are inserted between the output terminals of the amplifiers B₁, B₂ and B₃ to average the adjacent amplified differences and generate intermediate average signals vₒ₄<1>, vₒ₄<2> and vₒ₄<3>. For example, the voltage divider vd_{b2} averages the intermediate amplified signals vₒ₃<1> and vₒ₃<2> to generate the intermediate average signal vₒ₄<2>; and the voltage divider vd_{b3} averages the intermediate amplified signals vₒ₃<2> and vₒ₃<3> to generate the intermediate average signal vₒ₄<3> and so on.

The following takes the digital data D₂ as an example. In FIG. 4, the voltage dividers vdᵢ₁ vdᵢ₂, and vd_{b2} counteracts the noise and offset defects of the amplifiers A₁, A₂, A₃, B₁ and B₂. Thus, the quality of the digital signal D₂ is dramatically improved.

Another exemplary embodiment of the ADC integrates the output stage voltage divider array (302 of FIG. 3) into the ADC of FIG. 4, wherein the output stage voltage divider array 302 is coupled between the comparator array 206 and the latch array 208.

Another exemplary embodiment of the ADC comprises more than one intermediate stage (each intermediate stage comprises an intermediate stage amplifier array 402 and an intermediate stage voltage divider array 404 as shown in FIG. 4) between the input stage voltage divider array 204 and the comparator array 206.

Some exemplary embodiments of the invention may take the aforementioned input stage voltage divider array 204 and output stage voltage divider array 302 as optional components. For example, an ADC comprising only the intermediate stage voltage divider array 404 but neither of the input stage voltage divider array 204 and the output stage voltage divider array 302 is in the scope of our invention.

Some exemplary embodiments of the invention may take the input stage voltage divider array 204 and intermediate stage voltage divider array 404 as optional components. For example, an ADC comprising only the output stage voltage divider array 302 but neither of the input stage voltage divider array 204 and the intermediate stage voltage divider array 404 is in the scope of our invention.

ADCs comprising any of the aforementioned voltage divider arrays 204, 302 and 404 are in the scope of our invention.

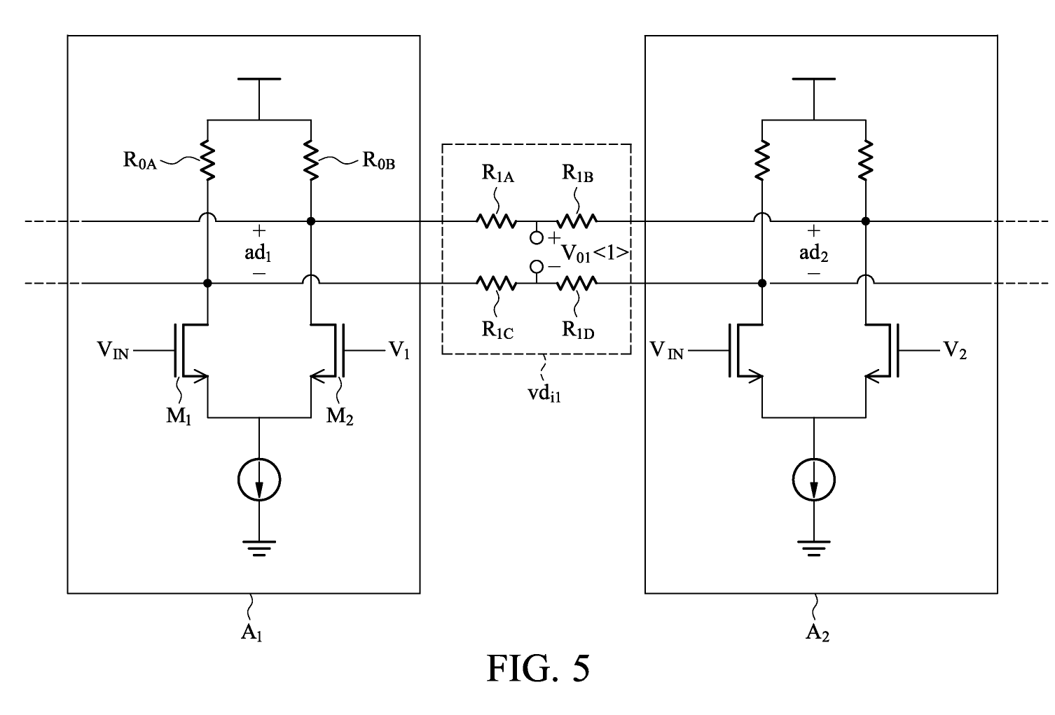

FIG. 5 illustrates an exemplary circuit of the amplifiers A₁ and A₂, and the voltage divider vdᵢ₁. The voltage divider vdᵢ₁ comprises resistors R_{1A}, R_{1B}, R_{1C} and R_{1D}. The amplifier A₁ comprises a pair of transistors M₁ and M₂ (forming a differential pair) and a pair of resistors R_{0A} and R_{0B}. The amplifier A₁ has a gain G, wherein

$$G = \frac{{ad}_{1}}{{V}_{in} - {V}_{1}} = {g}_{m 0} B {\sum }_{k = - N}^{N} {C}^{\vert k \vert - 1} \frac{1 - {( k γ )}^{2}}{\sqrt{1 - \frac{{( k γ )}^{2}}{2}}} , \qquad Formula ( 1 )$$

where gₘ₀ is the maximum transconductance of the differential pair. When the resistors R_{0A} and R_{0B} are of the same resistance R₀ and the resistors R_{1A}, R_{1B}, R_{1C} and R_{1D} follow the following equation, R_{1A}=R_{1B}=R_{1C}=R_{1D}=R₁/2, the values of B and C of Formula (1) are:

$$B = \frac{{R}_{1}}{2} ( \frac{1 + 2 \frac{{R}_{0}}{{R}_{1}}}{\sqrt{1 + 4 \frac{{R}_{0}}{{R}_{1}}}} - 1 ) ; C = \frac{2 \frac{{R}_{0}}{{R}_{1}}}{1 + 2 \frac{{R}_{0}}{{R}_{1}} + \sqrt{1 + 4 \frac{{R}_{0}}{{R}_{1}}}} .$$

When the reference signals for adjacent amplifiers follow the equation, V₁−V₂=V₂−V₃=V₃−V₄= . . . =V_{R}, and the overdrive voltage of the differential pair is V_{OVD}, the value γ of Formula (1) follows the following equation,

$$γ = \frac{{V}_{1} - {V}_{2}}{\sqrt{2} {V}_{OVD}} = \frac{{V}_{R}}{\sqrt{2} {V}_{OVD}} .$$

Furthermore, the value N of the Formula (1) is 1/γ, indicating the number of working amplifiers of the circuit of FIG. 4.

For example, when the resistance R₀ is 2KΩ, the resistance R₁ is 200Ω and the overdrive voltage V_{OVD} is 100 mV, the voltage value V_{R} is 7.8 mV, and the maximum transconductance of the differential pair gₘ₀ is 2 mA/V, and the gain G of the amplifier A₁ is 3.9. When the consecutive amplifier B₁ has an offset defect of 30 mV, it involves the offset of the amplifier A₁ by 7.7 mV (30 mV/3.9).

If the voltage divider vdᵢ₁ is coupled between the amplifiers A₁ and A₄ rather than between the amplifiers A₁ and A₂, the value γ is 3 times larger than the aforementioned one

$$γ = \frac{{V}_{1} - {V}_{4}}{\sqrt{2} {V}_{OVD}} = \frac{3 {V}_{R}}{\sqrt{2} {V}_{OVD}} .$$

In this case, the gain G of the amplifier A₁ is 3.2. The 30 mV offset defect of the amplifier B₁ involves the offset of the amplifier A₁ by 9.4 mV (30 mV/3.2), which is worse than the aforementioned case. Thus, the ADCs of the invention, which insert voltage dividers between the adjacent outputs of an amplifier array, have a much better performance than the ADCs which try to solve the amplifier defects by coupling the amplifiers that are far apart from each other.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An analog to digital converter, comprising:
an input stage amplifier array, calculating and amplifying differences between an input signal and a plurality of reference signals to generate a plurality of amplified differences;
an input stage voltage divider array, averaging every two adjacent amplified differences to generate a plurality of average signals;
a comparator array, comparing the average signals with a threshold value to generate a plurality of compared results; and
an encoder, transforming the compared results to digital data to label the value of the input signal.

2. The analog to digital converter as claimed in claim 1, wherein the encoder further comprises:
an output stage voltage divider array, averaging every two adjacent compared results to generate a plurality of average compared results; and
a latch array, receiving the average compared results and outputting the digital data.

3. An analog to digital converter, comprising:
an input stage amplifier array, calculating and amplifying differences between an input signal and a plurality of reference signals to generate a plurality of amplified differences;
an input stage voltage divider array, averaging every two adjacent amplified differences to generate a plurality of average signals;
an intermediate stage amplifier array, amplifying the average signals to generate a plurality of intermediate amplified signals;
an intermediate stage voltage divider array, averaging every two adjacent intermediate amplified signals to generate a plurality of intermediate average signals to be coupled to a comparator array;
the comparator array, comparing the received signals with a threshold value to output a plurality of compared results; and
an encoder, transforming the compared results to digital data to label the value of the input signal.

4. The analog to digital converter as claimed in claim 3, wherein the encoder further comprises:
an output stage voltage divider array, averaging every two adjacent compared results to generate a plurality of average compared results; and
a latch array, receiving the average compared results and outputting the digital data.

5. An analog to digital converter, comprising:
an input stage amplifier array, calculating and amplifying differences between an input signal and a plurality of reference signals to generate a plurality of amplified differences;
an intermediate stage amplifier array, amplifying the amplified differences to generate a plurality of intermediate amplified signals;
an intermediate stage voltage divider array, averaging every two adjacent intermediate amplified signals to generate a plurality of intermediate average signals to be coupled to a comparator array;
the comparator array, comparing the received signals with a threshold value to output a plurality of compared results; and
an encoder, transforming the compared results to digital data to label the value of the input signal.

6. The analog to digital converter as claimed in claim 5, wherein the encoder further comprises:
an output stage voltage divider array, averaging every two adjacent compared results to generate a plurality of average compared results; and
a latch array, receiving the average compared results and outputting the digital data.
